(19) United States
(12) Patent Application Publication
(10) Pub. No.: US 2011/0128018 A1
(43) Pub. Date: Jun. 2, 2011

(54) SWITCHING STRIP FOR DETECTION OF OBSTRUCTIONS, AND APPARATUS FOR THE DETECTION OF OBSTRUCTIONS

(76) Inventors: Gerd Reime, Buehl (DE); Thomas Wiest, Ochsenhausen (DE); Marc Scherraus, Ulm (DE)

(21) Appl. No.: 12/737,632

(22) PCT Filed: Jul. 31, 2009
(86) PCT No.: PCT/EP2009/005576

§ 371 Date: Jan. 31, 2011

(30) Foreign Application Priority Data
Jul. 31, 2008 (DE) 10 2008 035 634.4

(51) Int. Cl. G01R 27/26; H02G 3/00

(52) U.S. Cl. 324/679; 174/70 R

(57) ABSTRACT

A switching strip profile for a switching strip for the detection of obstructions, and an apparatus for the detection of obstructions. The switching strip profile has a profiled body composed of electrically non-conductive material, a first conductor which is arranged in a rear area of the profiled body, and a second conductor which is arranged in a front area of the profiled body. The first conductor has two side surfaces which run essentially parallel to and at a short distance from a respective outer wall of the profiled body, and, on a lower face which faces an attachment surface of the profile, the first conductor has a U-like shape which is open towards the attachment surface.

The invention relates to switching strip profile for a switching strip for the detection of obstructions having a profiled body of electrically non-conductive material, a first conductor arranged in a rear area of the profiled body seen in the detection direction and a second conductor arranged in a front area of the profiled body seen in the detection direction. The invention also relates to an apparatus for the detection of obstructions having a switching strip profile in accordance with the invention.

A switching strip for detection of obstructions and intended for the capacitive detection of obstructions is known from the German published application DE 10 2006 015 687 A1. A first conductor arranged in a rear area of the profiled body seen in the detection direction acts there as a so-called shield electrode, and a second conductor arranged in a front area of the profiled body seen in the detection direction serves to generate an electrical field. Starting from the second conductor, field lines will extend through the profiled body and to a reference electrode, for example a vehicle body. The first conductor is intended to prevent the field extending directly from the second conductor to the reference potential counter to the detection direction. The first conductor is here maintained as a shield electrode at a potential approximating to the potential of the second conductor. If an obstruction moves into the field between the second conductor and the vehicle body, the capacitance between the second conductor and the vehicle body changes, and can for example be detected by monitoring the voltage at the second conductor. A major problem with these known switching strips is that the generation of the electrical field and the evaluation of a change in the capacitance between the switching strip and the reference potential take place at one and the same electrode. The result is that for example wetting of the switching strip with water already causes a major signal corruption and may thwart the detection of an obstruction.

The invention is intended to provide a switching strip profile for detection of obstructions in which reliable detection of obstructions can be achieved with capacitive detection, and that is impervious to interfering effects, for example wetting of the switching strip.

In accordance with the invention, a switching strip profile is provided to do so for a switching strip for detection of obstructions having a profiled body of electrically non-conductive material, a first conductor arranged in a rear area of the profiled body seen in the detection direction and a second conductor arranged in a front area of the profiled body seen in the detection direction, where the first conductor has, seen in a cross section of the profile, two side surfaces running substantially parallel and at a short distance from a respective outer wall of the profiled body. In particular, the first conductor on an underside facing an attachment surface of the profiled body can have a U-shaped form opened towards the attachment surface.

The switching strip profile in accordance with the invention is intended for the capacitive detection of obstructions, where the electrical field whose influencing by obstructions is used to detect such obstructions is generated by the first conductor, and the second conductor receives this field and then also emits it. The first conductor is to that end connected to a control unit with low resistance, while the second conductor is connected to the control unit with high resistance, and is hence not supplied by the control unit with a signal serving to generate the electrical field. Instead, at the second conductor a signal is picked up only with high resistance and is an indicator of a change in the capacitance between the second conductor and the reference electrode. In this way, a possible wetting of the profiled body with water, ice or the like no longer has any influence and cannot affect the detection of obstructions. To support this imperviousness to netting of the profiled body, the first conductor has, seen in a cross section of the profile, two side surfaces running substantially parallel and at a short distance from a respective outer wall of the profile. With a design of this type for the two side surfaces of the first conductor, a comparatively high capacitance is created between the first conductor and the side outer walls of the profiled body. Any water film adhering to the outside of the profiled body is thus detected by the field lines extending from the first conductor and possibly diverts these field lines in the direction towards the reference electrode. This however does not influence the impingement on the second conductor by the electrical field extending from the first conductor as the latter is supplied with low resistance. A water film does not however influence the amplitude picked up with high resistance at the second conductor, i.e. the measurement signal, since no substantial change in the field line distribution between the second conductor and the reference electrode occurs due to the water film either. A comparatively high capacitance due to the specific design of the side surfaces of the first conductor between the first conductor and the outer surfaces of the profiled body thus favors the imperviousness of the switching strip to wetting of the profiled body during capacitive detection of obstructions. Since the first conductor has on its underside facing an attachment surface of the profiled body a U-shaped form opened towards the attachment surface, a reduction in the capacitance between the first conductor and the attachment surface is achieved when compared with a straight-lined design of the first conductor in this area. Switching strips when used in motor vehicles are usually fastened on the electrically conductive vehicle body which acts at the same time as the reference electrode. As low as possible a capacitance between the first conductor and the reference electrode prevents any influence being exerted on the transmitting system with the first conductor due to an unwelcome low-pass influence by the capacitance between the first conductor and the reference electrode.

In a further embodiment of the invention, the first conductor has on its upper side facing the second conductor a U-shaped form opened towards the second conductor.

In this way, a comparatively low capacitance is achieved between the first conductor and the second conductor. This comparatively low capacitance between the first conductor and the second conductor favors sensitivity during capacitive detection of obstructions. An obstruction in the detection range of the switching strip alters the capacitance between the second conductor and a reference electrode. This change in the capacitance is detected by a change in the signal picked up with high resistance at the second conductor, where the second conductor forms the pickup point of a capacitive voltage divider. If the capacitance between the first conductor and the second conductor is rather low, this improves the sensitivity of detection, since the capacitance between the second conductor and the reference electrode is also low due the necessarily large distance between the second conductor and the reference electrode.

In a further embodiment of the invention, a front surface of the second conductor, at the front when seen in the detection direction, is substantially parallel to an outer surface of the profiled body.

In this way, the formation of regions of increased field strength between the outer surface of the profiled body and the front surface of the second conductor can be prevented. This would not per se be a problem with profiled bodies that are unsoiled and dry, but if the outer surface of the profiled body is for example wetted with water, these regions of increased field strength could cause a falsification of the obstruction detection.

In a further embodiment of the invention, the front surface of the second conductor is arranged at a distance from the outer surface of the profiled body which is greater than the distance of the side surfaces of the first conductor from a respective side outer wall of the profiled body.

In this way, a capacitance between the second conductor and the outer surface of the profiled body is lower than a capacitance between the first conductor and the outer surfaces of the profiled body, so that any wetting of the outer surface of the profiled body, for example by a water film, is influenced more by the first conductor than by the second conductor. The effect of wetting on the electrical field generated by the second conductor thus remains minor.

In a further embodiment of the invention a front surface of the second conductor is designed arc-shaped when seen in the cross section of the profile.

With this arc-shaped design for the front surface of the second conductor, the area of this front surface is increased compared with a straight-lined design. Hence the detection area of the switching strip too is increased and the sensitivity in respect of the detection of obstructions can be improved.

In a further embodiment of the invention, the profiled body has a cavity abutted by an underside of the second conductor and an upper side of the first conductor.

A cavity of this type, typically filled with a gas, for example air, between the first conductor and the second conductor contributes to a reduction of the capacitance between the first conductor and the second conductor. As already explained, the sensitivity of the switching strip with regard to the detection of obstructions can thus be improved.

In a further embodiment of the invention, the second conductor and/or the first conductor have a projection protruding into the cavity in the direction of the first conductor or second conductor respectively.

This design of the second conductor and/or of the first conductor can create an additional possibility for tactile detection of obstructions: if a force is exerted onto the detection area of the switching strip in the direction of its attachment surface, the second conductor is moved towards the first conductor until the two conductors are touching. This touching of conductors can of course be detected either by the abruptly reduced electrical resistance between the first and the second conductor or by the abruptly reduced capacitance between the first and second conductors. In this way, a tactile detection of obstructions is also possible in addition to contactless capacitive detection of obstructions.

The problem underlying the present invention is also solved by an apparatus for the detection of obstructions with a switching strip in accordance with the invention, where a control unit is provided which is coupled with low resistance to the first conductor and with high resistance to the second conductor, where an electrical field is generated in operation by means of the control unit and the first conductor, where an electrical field is formed between the second conductor and a reference potential due to the electrical field generated by the first conductor by capacitive coupling between the first conductor and the second conductor, and where a change in the capacitance between the second conductor and the reference potential caused by a obstruction is detected by the control unit.

Because the first conductor is coupled with low resistance to the control unit and the second conductor with high resistance, the apparatus in accordance with the invention for detection of obstructions is impervious to wetting of an outer surface of the switching strip, for example by raindrops, since the second conductor is not supplied with a signal from the control unit, but receives the signal emitted by the first conductor thanks to the capacitive coupling between the first conductor and the second conductor. Because of the high-resistance coupling of the second conductor to the control unit, the potential at the second conductor hence substantially follows the signal behavior at the first conductor and the second conductor likewise emits a signal, with an electrical field forming between the second conductor and the reference electrode. The second conductor is coupled with high resistance to the control unit and thus the control unit only picks up a signal from the second conductor, for example, a voltage at the second conductor characterizing a capacitance or change in capacitance between the second conductor and the reference electrode. The apparatus in accordance with the invention is thus impervious to environmental effects, such as wetting of an outer surface of the switching strip, and reliable contactless detection of obstructions is possible. Low resistance is regarded here as a resistance of less than 200 Ω, and high resistance as a resistance of more than 50 Ω. The high-resistance connection thus has a resistance of at least 250 times that of the low-resistance connection. The control unit can have a bridge circuit with a low-resistance branch and a high-resistance branch, the first conductor being connected to the low-resistance branch and the second conductor to the high-resistance branch.

In a further embodiment of the invention, the first conductor and the second conductor are connected with high resistance by means of a terminating resistor.

The high-resistance connection between the first conductor and the second conductor must be designed such that it has only a negligible influence on the signal transmission between the first and the second conductors compared with the capacitive coupling between the first and second conductors. Nevertheless, a high-resistance connection of this type by means of a terminating resistor can permit a reliable check on the functioning of the switching strip; since in the event of a break in the switching strip no connection whatsoever would be possible between the first conductor and the second conductor via the terminating resistor, and any damage to the switching strip can be detected. It goes without saying that the control unit must have means for detection of any interruption in the first and/or the second conductor.

In a further embodiment of the invention, the control unit has means for detection of a mutual contact of the first conductor and second conductor.

Besides contactless detection of obstructions, an additional tactile detection by the apparatus in accordance with the invention can also be achieved as a result. The substantial change in capacitance between the first conductor and the second conductor resulting from contact of the first and the second conductor can for example be achieved. It is also possible to detect an ohmic resistance or a capacitance between the first conductor and the second conductor that likewise considerably alters when contact is made.

The additional tactile detection can be achieved either by detection of a displacement of the two conductors relative to one another that changes the capacitance between the first and second conductors, or by a quiescent current measurement of a quiescent current flowing through the two conductors via the terminating resistor or the terminating capacitance. Instead of the terminating resistor, electrical or electronic components can be generally used, for example integrated circuits, transponders, diodes, temperature-sensitive resistors, inclination sensors or the like. Using the example of using a resistor with negative temperature coefficients, an evaluation of the amount of quiescent current can provide information on a temperature in the area of the switching strip. Depending on the temperature, a vehicle tailgate can then for example be moved quickly or slowly.

Further advantages and features of the invention can be gathered from the claims and from the following description of preferred embodiments of the invention in conjunction with the drawings. Individual features of the various embodiments shown in the figures can be combined with one another as required without departing from the scope of the invention. The drawings show in:

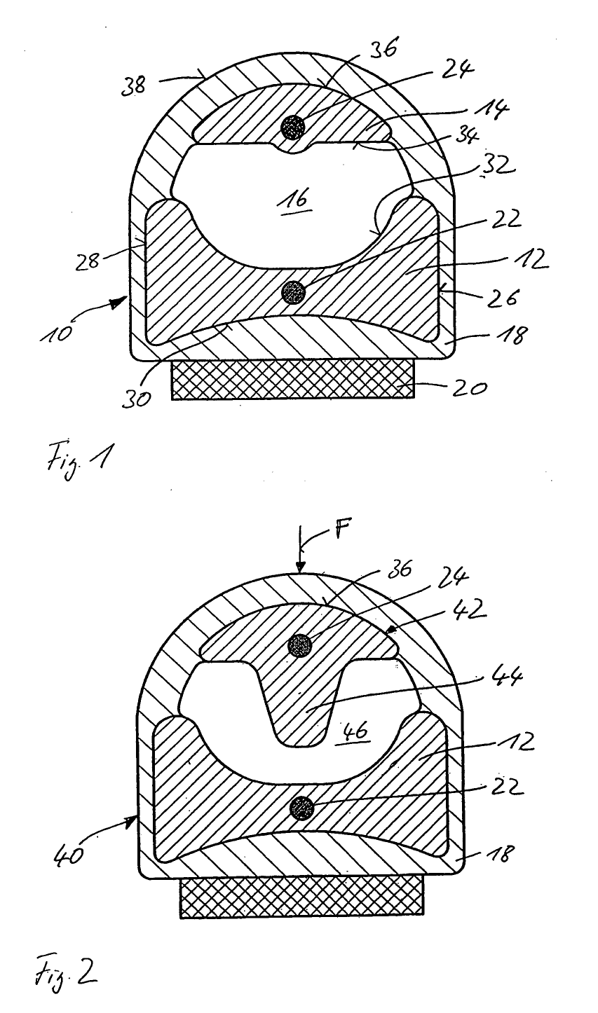

FIG. 1 a sectional view of a switching strip profile in accordance with a first embodiment of the invention,

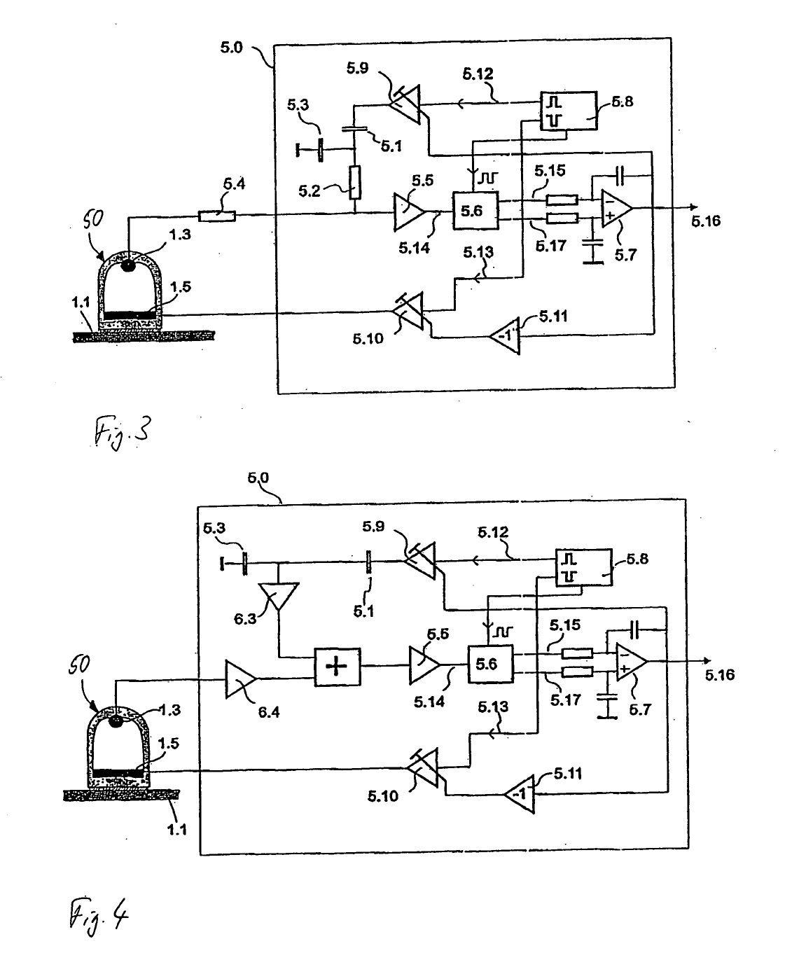

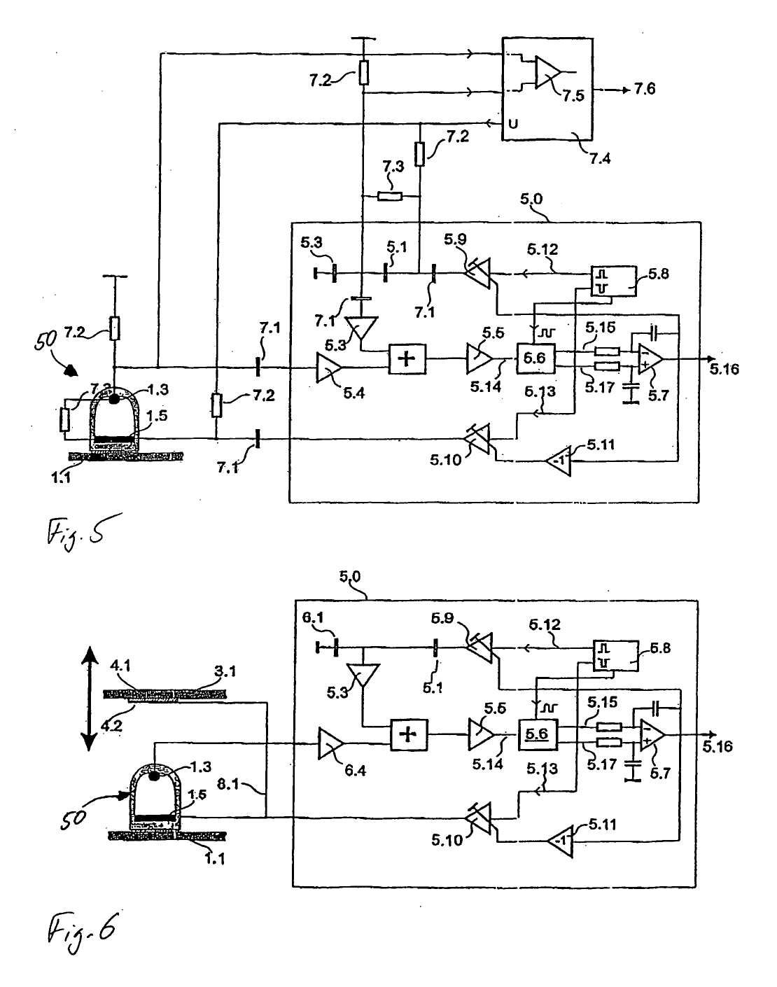

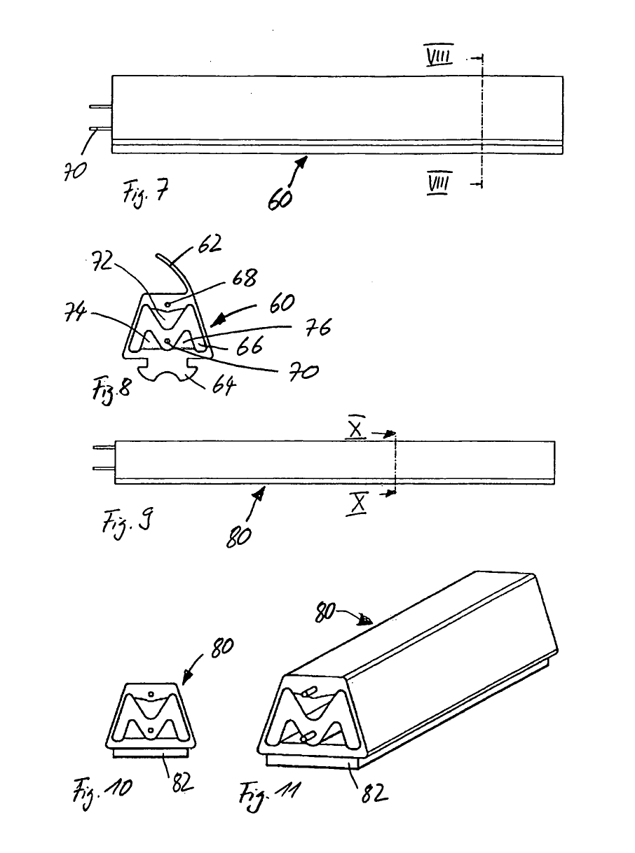

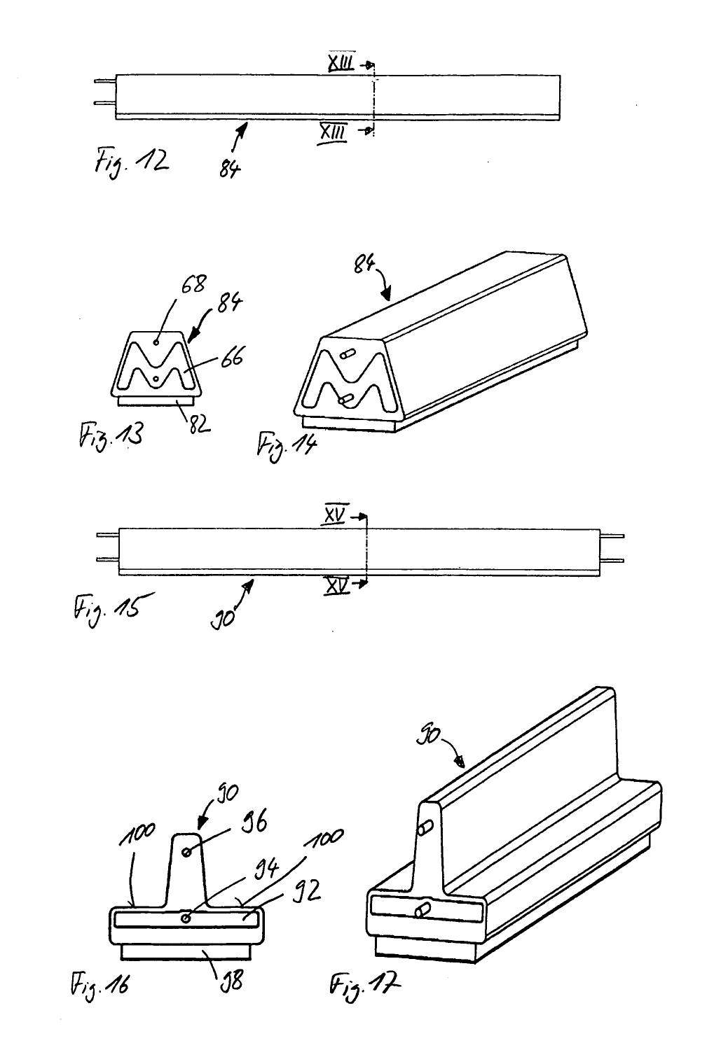

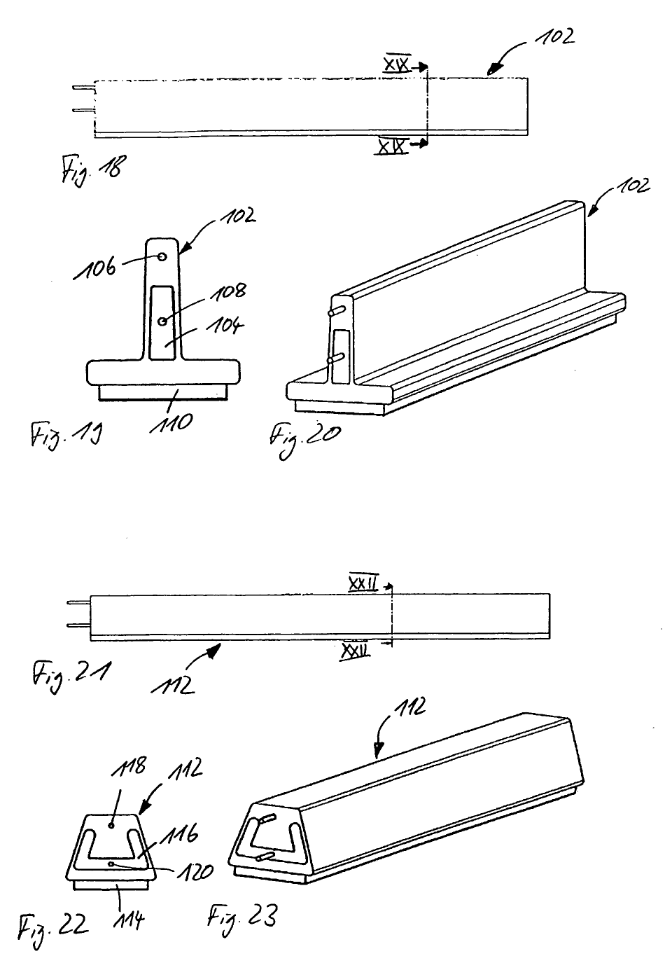

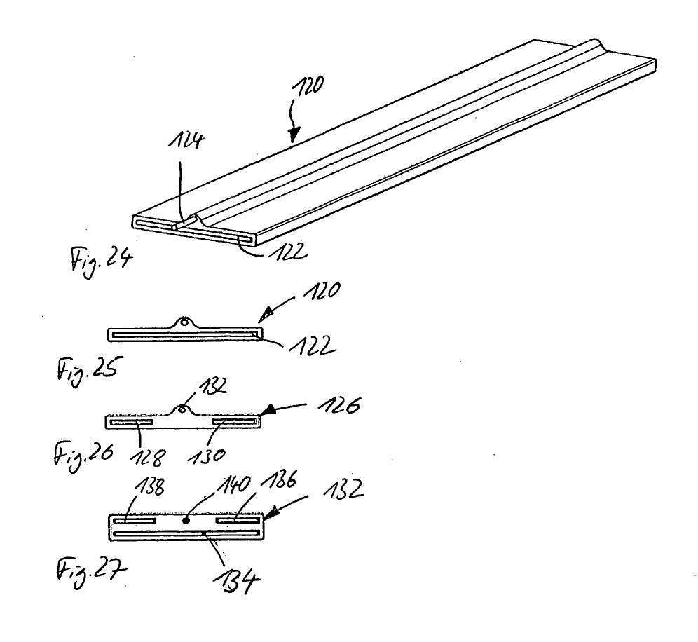

FIG. 2 a sectional view of a switching strip profile in accordance with a second embodiment of the invention,

FIG. 3 a block diagram of a circuit for detection of capacitive changes in an inventive switching strip profile,

FIG. 4 a block diagram in accordance with FIG. 3 in which the summation resistors are replaced by impedance converters,

FIG. 5 a block diagram in accordance with FIG. 3 with a circuit for monitoring the switching strip for mechanical damage and deformation,

FIG. 6 a block diagram in accordance with FIG. 4, where a further conductor is connected,

FIG. 7 a side view of a switching strip profile in accordance with a third embodiment of the invention,

FIG. 8 a sectional view of the switching strip profile from FIG. 7 onto the sectional plane VIII-VIII,

FIG. 9 a side view of a switching strip profile in accordance with a fourth embodiment of the invention,

FIG. 10 a sectional view of the switching strip profile from FIG. 9 onto the sectional plane X-X,

FIG. 11 an isometric representation of the switching strip profile from FIG. 9,

FIG. 12 a side view of a switching strip profile in accordance with a fifth embodiment of the invention,

FIG. 13 a sectional view of the switching strip profile from FIG. 12 onto the sectional plane XIII-XIII,

FIG. 14 an isometric representation of the switching strip profile from FIG. 12,

FIG. 15 a side view of an inventive switching strip profile in accordance with a sixth embodiment of the invention,

FIG. 16 a sectional view of the switching strip profile from FIG. 15 onto the sectional plane XVI-XVI of FIG. 15,

FIG. 17 an isometric representation of the switching strip profile from FIG. 15,

FIG. 18 a side view of an inventive switching strip profile in accordance with a seventh embodiment of the invention,

FIG. 19 a sectional view of the switching strip profile from FIG. 18 onto the sectional plane XVIII-XVIII,

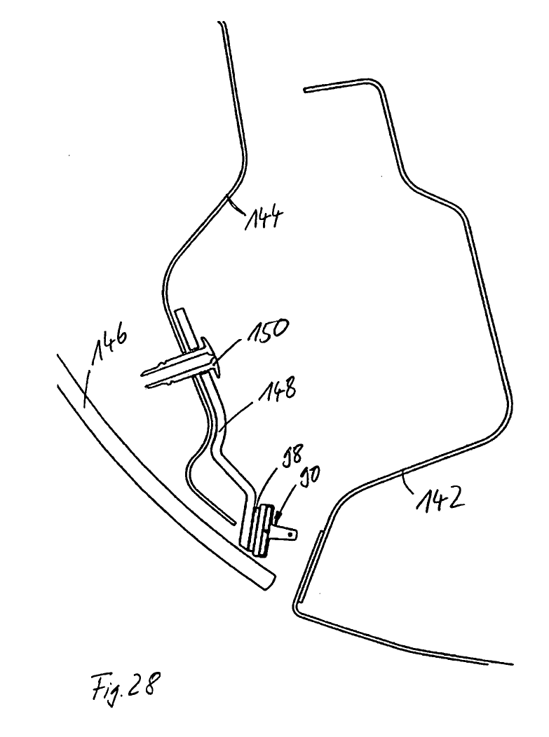

FIG. 20 an isometric representation of the switching strip profile from FIG. 18,

FIG. 21 a side view of a switching strip profile in accordance with an eighth embodiment of the invention,

FIG. 22 a sectional view of the switching strip profile from FIG. 21 onto the sectional plane XXII-XXII,

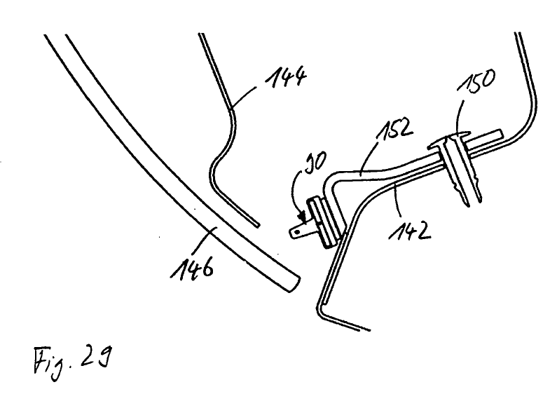

FIG. 23 an isometric representation of the switching strip profile from FIG. 21,

FIG. 24 an isometric representation of an inventive switching strip profile in accordance with a ninth embodiment of the invention,

FIG. 25 a sectional view of the switching strip profile from FIG. 24,

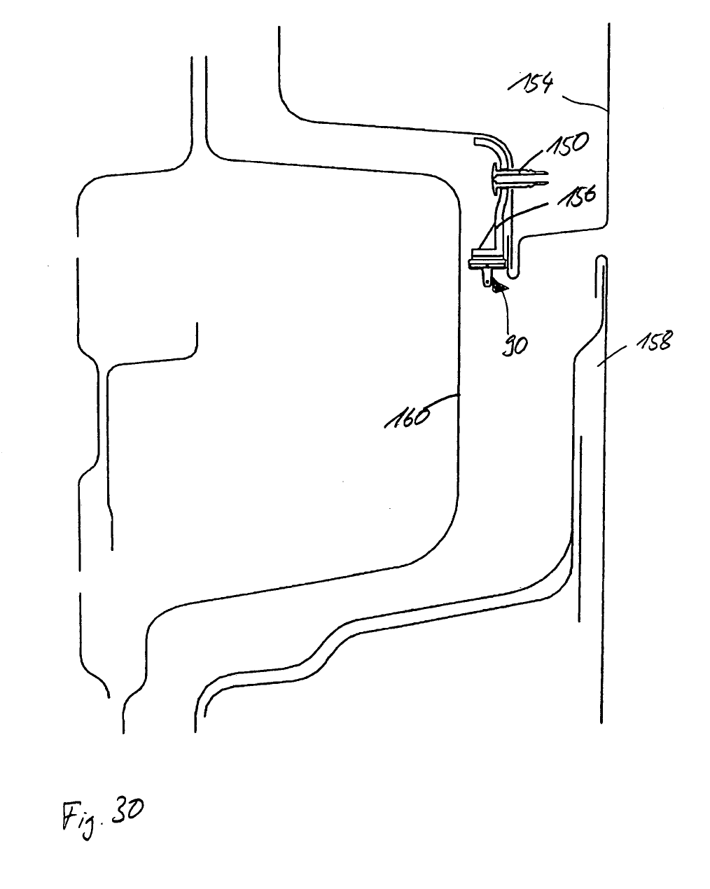

FIG. 26 a sectional view of a switching strip profile in accordance with a tenth embodiment of the invention,

FIG. 27 a sectional view of a switching strip profile in accordance with an eleventh embodiment of the invention,

FIG. 28 a schematic horizontal section through a part of a vehicle in the area of its tailgate, the vehicle being provided on the tailgate side with a switching strip profile according to FIGS. 15, 16 and 17,

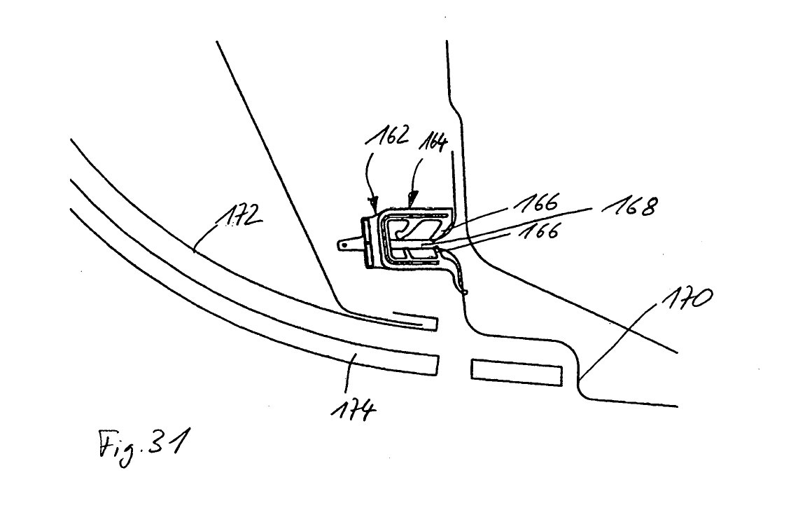

FIG. 29 a schematic horizontal section through a part of a vehicle which in the area of its tailgate is provided on the body side with a switching strip profile according to FIGS. 15, 16 and 17,

FIG. 30 a schematic horizontal section through a part of a vehicle which in the area of its side sliding door is provided with a switching strip profile according to FIGS. 15, 16 and 17, and

FIG. 31 a schematic horizontal section through a part of a vehicle in the area of its tailgate, the vehicle being provided on the tailgate with a switching strip profile according to FIGS. 15, 16 and 17.

In the illustration in FIG. 1, it can be seen that a switching strip profile 10 has a first electrical conductor 12 and a second electrical conductor 14, between which an air-filled cavity 16 is arranged. Both conductors 12, 14 are extruded jointly with an electrically non-conductive profiled body 18. The profiled body 18 also carries on its underside an attachment strip 20, for example an adhesive strip. The conductors 12, 14 are each formed by areas of conductive plastic, each of these areas having a wire strand 22, 24 in a central area. The switching strip profile shown in FIG. 1 is manufactured by extrusion. During extrusion, the wire strands 22, 24 are also inserted at the same time.

The first conductor 12 has a cross section with a generally H-shaped or bone-shaped form. The first conductor has two side surfaces 26, 28 each arranged parallel to and at a short distance from a respective outer surface of the profiled body 18. The side surfaces 26, 28 extend over approximately half the height of the profiled body 18 parallel to its right-hand or left-hand outer surface respectively. The distance between the side surfaces 26, 28 and the respective outer surface of the profiled body is comparatively short, in order to obtain a comparatively high capacitance between these outer surfaces and the side surfaces 26, 28.

A lower limitation of the first conductor 12 facing the attachment strip 20 has a U-shaped form which is opened towards the attachment strip 20. Contrary to the detection direction or downwards from the wire strand 22 when seen towards the attachment strip, the lower limiting surface of the first conductor 12 thus has a concave and inwardly curved form. The switching strip profile 10 is, at any rate when used in motor vehicles, usually fitted or glued onto the metallic vehicle body. Thanks to the concave design of the lower limiting surface of the first conductor 12, the capacity can be reduced between the first conductor 12 and an electrically conductive body in order to prevent an unwelcome low-pass influence.

An upper limiting surface 32 adjoining the cavity 16 and facing the second conductor 14 is, when seen from the first conductor, likewise designed inwardly curved or concave. Seen in cross section, the upper limiting surface 32 of the first conductor 12 thus has a U-shaped form. A concave design of this type of the limiting surface 31 of the first conductor 12 facing the second conductor 14 allows a capacitance between the first conductor 12 and the second conductor 14 to be kept low. It also improves the sensitivity of the capacitive detection of obstructions, since a capacitive voltage divider is formed from the capacitance between the first conductor 12 and the second conductor 14, and the second conductor and a reference electrode, for example earth, for the detection of obstructions. A voltage is then for example picked up at the second conductor 14 via a high-resistance link to a control unit. A capacitance between the second conductor 14 and the reference electrode is very low anyway because of the usually large distance, so that a low capacitance between the first conductor 12 and the second conductor 14 improves sensitivity.

In relation to the generated capacitances, the first conductor 12 would ideally have an H-shape, i.e. two lateral strips instead of the side surfaces 26, 28, linked by means of a horizontal transverse strip.

During manufacture of the switching strip profile 10, the profiled body 18, the first conductor 12 and the second conductor 14 are jointly extruded, with the first conductor 12 and the second conductor 14 being manufactured from conductive plastic and the profiled body 18 from non-conductive plastic. Simultaneously with extrusion, the wire strands 22, 24 are inserted. The attachment strip 20 can be joined on later.

The second conductor 14 has, seen in cross section, approximately the form of a circular segment, where a lower limiting surface 34 adjoining the cavity 16 and facing the first conductor 12 is designed approximately flat. Only in the middle of the lower limiting surface 34, a cylinder section-shaped elevation is arranged. This elevation is used to embed the wire strand 24 on the side of the lower limiting surface 34 too, completely and with a certain material thickness. A front surface 36 of the second conductor 14, positioned at the front when seen in the detection direction, is designed circle-segment—shaped when seen in cross section. The overall result is a cross section approximately in the form of a circle segment. The front surface 36 acting as the detection surface and from which extends the electrical field, the change of which permits verification of a obstruction, can thus be designed with a larger surface, thereby also improving the sensitivity of detection. The front surface 36 is furthermore arranged parallel to an outer surface 38 of the profiled body 18 in the upper area of the switching strip profile 10. A capacitance between the front surface 36 of the second conductor 14 and the outer surface 38 of the profiled body 18 is therefore substantially constant when seen over the front surface 36. Local field strength peaks that might impair detection are therefore also not formed when the outer surface 38 is wetted by water droplets, dirt or frost.

Moreover, the front surface 36 of the second conductor 14 is arranged at a greater distance from the outer surface 38 of the profiled body 18 than the two side surfaces 26, 28 of the first conductor 12. The capacitance between the front surface 36 and the outer surface 38 is thus smaller than the capacitance between the respective side surfaces 26, 28 and the outer surface 38. In any event, water droplets for example wetting the outer surface 38 in the lower area of the switching strip profile 10, are influenced more by the first conductor 12 than by the second conductor 14. Due to the low-resistance link of the first conductor 12, the obstruction detection is not impaired as a result.

The illustration in FIG. 2 shows a sectional view of a further switching strip profile 40 in accordance with a further embodiment of the invention. Only the features differing from the switching strip profile 10 of FIG. 1 are explained. Identically designed elements are provided with the same reference numbers as in FIG. 1. The switching strip profile 40 has, like the switching strip profile 10 of FIG. 1, a profiled body 18 and a first conductor 12 and also an attachment strip 20 which are designed identical to the respective elements of the switching strip profile 10 of FIG. 1. A second conductor 42 is arranged above the first conductor, seen in detection direction, i. e. from the first conductor 12 in the direction of the second conductor 42. A front surface 36 of the second conductor 42 is designed identical to the front surface 36 of the second conductor 14 of FIG. 1. The second conductor 42 however has a projection 44 protruding into a cavity 46 between the first conductor 12 and the second conductor 42. The projection 44 is designed approximately trapezoidal, seen in the cross section in FIG. 2, a width of the projection 44 decreasing in the direction of the first conductor 12. The cavity 46 is, like the cavity 16 of the switching strip profile 10 of FIG. 1 air-filled and vented. In the event of a compression of the switching strip profile 40 by a force F, the elastic profiled body 18 will thus deform until an underside of the projection 44 is contacting the first conductor 12. Thanks to this contact between the first conductor 12 and the second conductor 42, both the capacitance and the resistance between the first conductor 12 and the second conductor 42 decrease markedly. In this way, tactile detection of obstructions is possible additionally to their contactless capacitive detection.

The U-shaped design of the upper side of the first conductor 12, facing the projection 44 permits, even if the profiled body 18 is compressed obliquely, and the projection 44 to cover the same distance for contacting the first conductor 12 as in the case of exactly perpendicular application of the force F indicated in FIG. 2. Up to an angle for the force F of ±45°, the projection 44 must always cover the same distance to contact the second conductor 12.

The block diagrams of FIGS. 3 to 6 make clear the mode of operation of an apparatus for detecting obstructions. It must be noted here that instead of the switching strip profile 50 shown in FIGS. 3 to 6 in an apparatus in accordance with the invention for detection of obstructions, the switching strip profile 10 of FIG. 1 or the switching strip profile 40 of FIG. 2 is used. A first conductor 12 is identified in the illustrations in FIGS. 3 to 6 with the reference number 1.5, a second conductor 14, 42 with the reference number 1.3.

Based on the illustration in FIG. 3, a pulse generator 5.8 supplies a first clock pulse 5.13 to a first amplitude controller 5.10 and a second inverted clock pulse 5.12 to a second amplitude controller 5.9. For example, an electrical alternating signal of, for example, 70 kHz is used. The low-resistance output of the first amplitude controller 5.10 is connected to the first conductive element 1.5, corresponding to the first conductor 12. This element transmits, thanks to capacitive effects, the first clock pulse 5.13 to the conductive element 1.3, corresponding to the second conductor 14, 42. The signal of the conductive element 1.3 is passed via the high-resistance summation resistor 5.4 to the input of the alternating voltage amplifier 5.5, and the second clock pulse 5.12, inverted to the first clock pulse 5.13, is passed via the second amplitude controller 5.9 to the reference series capacitor 5.1 and via a second high-resistance summation resistor 5.2 to the input of the alternating voltage amplifier 5.5. The reference series capacitor 5.1 should have approximately the same capacitance as the capacitance of the conductive elements 1.5 and 1.3 to one another. Any capacitance occurring of the first conductive element 1.3 relative to the environment, e.g. to the vehicle chassis, can be balanced out by the shunt capacitor 5.3. The summation resistors 5.2 and 5.4 should be preferably high-resistance and have the same values.

With corresponding amplitude control, the previously accumulated clock pulses 5.12 and 5.13 cancel each other out at the input of the amplifier 5.5, preferably designed as an alternating voltage amplifier. Since the amplifier 5.5 ideally only sees noise at the input after mutual neutralization of the clock pulses, it can amplify very strongly or be designed as a high-amplification limiter amplifier. The output signal 5.14 of the amplifier 5.5 is supplied to the synchronous demodulator 5.6. The output signals assignable to the two clock pulses 5.12 and 5.13 of the synchronous demodulator 5.6 are checked by the integrating comparator 5.7 for amplitude differences.

The comparator can be designed as a high-amplifying comparator circuit. Any divergence, however small, of the input voltages 5.15 and 5.17 leads to a corresponding divergence of the control value 5.16 of the current value. The amplitude controllers 5.9 and 5.10 are actuated inverted to one another with the control value 5.16 by means of the inverting stage 5.11. If the output amplitude of one amplitude controller increases, it falls accordingly in the other. As a result, the input signal of the alternating voltage amplifier 5.5 is kept continuously at “zero”, i.e. there are no pulse-synchronous signal portions whatsoever contained.

If for example a hand approaches the switching strip profile 50, the capacitance of the second conductive element 1.3 alters relative to the surroundings. This additional capacitance interacts with the capacitance between the conductive elements 1.5 and 1.3 similarly to a capacitive voltage divider, and the voltage at the element 1.3 drops accordingly. This drop leads at the input of the amplifier 5.5 to incomplete neutralization of the clock pulses 5.12 and 5.13. After synchronous demodulation in the synchronous demodulator 5.6 and evaluation of the divergence in the differences in the separated signal portions of the input voltages 5.15 and 5.17, this leads to a divergence of the control value 5.16.

If a hand approaches, the control value 5.16 changes to a higher control value. The difference in the control value 5.16 will rise or fall compared to a previous value until the clock pulse 5.13 and the inverted clock pulse 5.12 once again completely cancel each other out at the input of the alternating voltage amplifier 5.5.

In the design example, the control value increases when a hand approaches. An evaluation logic system, not shown, can then for example perform an evaluation of the control value 5.16 using a threshold value. If the threshold value is exceeded, this is deemed a trapping risk, and a mechanical movement can be stopped or reversed accordingly.

The summation resistors 5.2 and 5.4 described on the basis of FIG. 3 can also be replaced by capacitors or series connections of resistor and capacitor. In accordance with FIG. 4, the summation resistors 5.2 and 5.4 can also be designed with impedance converters 6.3 and 6.4 with high-resistance input. Thanks to the active circuit, the useful signal at the second conductive element 1.3 is not loaded.

A possibility for monitoring the switching strip 50 for mechanical damage is shown by the design example in FIG. 5. The evaluation electronics of the line monitor 7.4 provides a voltage which leads to corresponding voltages at the input of an evaluation circuit 7.5 via the resistors 7.2 and 7.3. At the mechanical end of the switching strip is the terminating resistor 7.3. An interruption of the current flow due to mechanical damage leads to a change in the voltage at the input of the evaluation circuit 7.5. The same applies for a mechanical compression of the switching strip in which the electrically conducting elements 1.5 and 1.3 make contact. Both states lead to corresponding output information 7.6 of the line monitor. The capacitors only act as blocking capacitors for disconnecting the DC voltage.

With the apparatus described using FIG. 5.4, this allows contactless detection of obstructions, tactile detection of obstructions and also monitoring of the switching strip 50 for breaks in the conductors 1.3 and 1.5.

The illustration in FIG. 6 shows an embodiment of an apparatus in accordance with the invention which is provided for example for a closing tailgate of a motor vehicle in which the moving tailgate 3.1 can move towards the switching strip 50 and away from it again. It can also be used for all types of externally operated doors, gates and flaps. When the closing tailgate, the moving element 3.1, is provided with only a thin conductive and flat element 4.2, the result is a simplification of the switching arrangement. A non-conducting surface, e.g. an adhesive tape 4.1, insulates the conductive flat element 4.2 from the metal surface of the moving element 3.1. The conductive element 4.2 and the first conductive element 1.5 are electrically connected via a cable 8.1. However, the conductive element 4.2 can also be connected via a voltage divider to the signal for the conductive element 1.5 to equalize any signal attenuations, e.g. due to a summation resistor 5.4, cf. FIG. 3. A further possibility is to connect the conductive element 4.2 to the same electrical potential as the second conductive element 1.3. To do so, the signal at the second conductive element 1.3 is picked up with high resistance and connected via an impedance converter to the conductive element 4.2. The important thing is however that when the tailgate is closed, i.e. when the conductive element 4.2 approaches the switching strip 1.2, there is no change in the control value 5.16. A finger in the trapping area alters the capacitance of the element 1.3 compared with the surroundings and is therefore reliably detected.

FIG. 7 shows a switching strip profile 60 in accordance with the invention that is shown in section in FIG. 8. The switching strip profile 60 is provided with a sealing lip 62 and an engaging projection 64. With the engaging projection 64, the switching strip profile 60 can for example be pulled into a rear groove and the sealing lip 62 can be used for sealing window frames or door frames.

The switching strip profile 60 is provided with two conductors 66, 68. The first conductor 66 has an M-like shape in cross section and is extruded from conductive elastic material.

In the middle of the first conductor 66 is arranged a wire strand 70, which can also be seen in FIG. 7 and protrudes at one end of the switching strip profile and hence can be connected to an electronic control unit. The second conductor 68 exclusively comprises a wire strand embedded into the elastic and non-conductive material of the switching strip profile 60.

An air-filled cavity 72 is arranged between the first conductor 66 and the second conductor 68, and further air-filled cavities 74, 76 are also arranged at the side of the wire strand 70 inside the first conductor 66. The air-filled cavity 72 ensures a low capacitance between the first conductor 66 and the second conductor 68. The air-filled cavities 74, 76 reduce a capacitance between the first conductors 66 and a carrier, not shown, connected to reference potential.

The crucial factor is that the side surfaces of the first conductor 66 are at a short distance from the parallel outer surface of the switching strip profile 60 and hence form a high capacitance also relative to any water droplets adhering to the outer surface.

The illustration in FIG. 9 shows a further switching strip profile 80 in accordance with the invention. The switching strip profile 80 is shown in section in FIG. 10 and in an isometric illustration in FIG. 11. The switching strip profile 80 of FIGS. 9, 10 and 11 differs from the switching strip profile 60 of FIGS. 7 and 8 in the omission of the sealing lip 62 and by the provision of a carrier sheet 82 instead of the engaging projection 64. The switching strip profile 80 can for example be affixed to a carrier with the carrier sheet 82.

The illustration in FIG. 12 shows in a side view a further switching strip profile 84 in accordance with the invention, which is shown in a sectional view in FIG. 13 and in an isometric illustration in FIG. 14. The switching strip profile 84 differs from the switching strip profile 80 of FIGS. 9, 10 and 11 only in that no air-filled cavities are provided between a first conductor 66 of M-shaped cross section and the second conductor 68. There are also no air-filled cavities present underneath the first conductor 66, i.e. between the first conductor 66 and the carrier sheet 82. A capacitance between the first conductor 66 and the second conductor 68, and between the first conductor 66 and a carrier material onto which the switching strip profile 84 is affixed, is thus higher than in the switching strip profile 80 of FIGS. 9 to 11, but the profile 84 is easier to manufacture.

The illustration in FIG. 15 shows a further switching strip profile 90 in accordance with the invention. The switching strip profile 90 is shown in a sectional view in FIG. 16 and in an isometric illustration in FIG. 17. The switching strip profile 90 has a first strip-like conductor 92 of rectangular cross section. A wire strand 94 is arranged in the middle of the first conductor 92. The first conductor 92 comprises conductive elastic material. During extrusion of the switching strip profile 90, two different elastic materials are extruded, namely the conductive material of the first conductor 92 and the non-conductive elastic material enclosing the first conductor 92 and into which a wire strand 96 is laid that forms a second conductor. The switching strip profile 90 is provided on its underside with a carrier sheet 98 which can then for example be affixed to a bodywork structure or other carrier.

As can be seen in FIG. 16, an upper side of the first conductor 92 is arranged parallel and at a short distance from the outer surface 100 of the switching strip profile 90. In the area of this outer surface 100, there is thus a high capacitance between the first conductor 92 and the outer surfaces 100. If moisture, for example in the form of droplets or frost, collects on these outer surfaces 100, the output signal of the switching strip 90 in accordance with the invention is thus either not affected or if so only insubstantially.

To prevent any collection of droplets of frost, and also of dirt, on the outer surfaces 100 and also on the other outer surfaces of the switching strip profile 90, the outside of the switching strip profile 90 can be provided with a hydrophobic coating. It is for example possible to provide the switching strip profile 90 with a so-called nano coating on its outside. When such nano coating is provided, water droplets form a critical angle of more than 90°, so that a surface with super-hydrophobic properties is created. Ideally, a so-called lotus effect with contact angles of around 160° is achieved. Water droplets thus roll off immediately and the interfering effects of moisture and dirt on the outer surfaces of the switching strip profile 90 are prevented. Such super-hydrophobic coatings can for example be sprayed on, wiped on or already applied during manufacture.

The illustration in FIG. 18 shows a switching strip profile 102 in accordance with the invention in a side view, FIG. 19 shows it in section and FIG. 20 in an isometric illustration.

The switching strip profile 102 has a first conductor 104 and a second conductor 106. The first conductor 104 comprises an area of extruded conductive elastic material slightly trapezoidal in cross section, in the middle of which a wire strand 108 is provided. The second conductor 106 comprises only a wire strand embedded in non-conductive elastic material of the switching strip profile 102.

The switching strip profile 102 has in its cross section an inverted T-shape, both conductors 104, 106 being arranged in an upward-extending web of the switching strip profile 102. The base of the T-shaped cross section comprises non-conductive elastic material and is provided on its underside opposite the web with a carrier sheet 110. The side surfaces of the second conductor 104 are parallel and at a short distance from the side surfaces of the upward-extending web.

FIG. 21 shows a further switching strip profile 112 in accordance with the invention, FIG. 22 shows it in section and FIG. 23 in an isometric illustration. The switching strip profile 112 has a basic shape which is trapezoidal in the cross section of FIG. 22 and which tapers upwards, i.e. in the detection direction, starting from an underside to which is fastened a carrier sheet 114. The switching strip profile 112 is provided with a first conductor 116 and a second conductor 118. The first conductor 116 comprises an approximately U-shaped area of conductive elastic material in the base of which a wire strand 120 is embedded. A distance between the sides of the second conductor 116 tapers parallel to the trapezoidal form of the switching strip profile 112. The second conductor 118 exclusively comprises a wire strand embedded into the non-conductive elastic material of the switching strip profile 112. The U-shaped design of the first conductor 116 favors a low capacitance between the first conductor 116 and the second conductor 118. The upper free ends of the sides of the first conductor 116 are designed rounded in order to prevent field strength peaks between the first conductor 116 and the second conductor 118. The outer side surfaces of the sides of the first conductor 116 are arranged parallel to and at a short distance from the outer surfaces of the switching strip profile 112.

A further embodiment of a switching strip profile in accordance with the invention is shown isometrically in FIG. 24 and in a front view in FIG. 25. The switching strip profile 120 is not extruded, but laminated. To that end, different coatings are placed on top of each other and bonded to one another in a suitable manner. The switching strip profile 120 has a strip-like first conductor 122 which can for example comprise a metal sheet. Above the first conductor 122, a second conductor 124 in the form of a wire strand is arranged. Elastic and non-conductive material is arranged between the first conductor 122 and the second conductor 124, and both the first conductor 122 and the second conductor 124 are enclosed completely at the sides by the non-conductive elastic material. The first conductor 122 and the second conductor 124 are accessible for contacting, if this is necessary, only at the front and rear ends respectively of the switching strip profile 120. As can be seen in the front view in FIG. 25, the first conductor 122 is arranged mostly parallel and at a short distance from an outer surface of the switching strip profile 120.

The illustration in FIG. 26 shows a front view of a further switching strip profile in accordance with the invention. A first conductor here comprises two metal strips 128, 130 arranged next to one another and a distance apart. The second conductor 132 in the form of a wire strand is arranged in the middle between the two metal strips 128, 130, the second conductor 132 being additionally displaced upwards in the detection direction relative to the two metal strips 128, 130. The two metal strips 128, 130 and the second conductor 132 are completely enclosed by elastic and non-conductive material with the exception of their front and rear ends respectively.

A further switching strip profile 132 in accordance with the invention is shown in a front view in FIG. 27. A first conductor of the switching strip profile 132 comprises a total of three metal strips 134, 136 and 138. A second conductor is formed by a wire strand 140. A first metal strip 134 extends substantially over the entire width of the switching strip profile 132. Two further narrower metal strips 136, 138 are arranged above the metal strip 134 and in each case flush with its outer edges. Each of the metal strips 136, 138 has somewhat less than a third of the width of the metal strip 134 and is arranged parallel to the latter. An area thus remains free between the two metal strips 136, 138 and the wire strand 140 is arranged in the middle between these two metal strips 136, 138. The three metal strips 134, 136, 138 and the wire strand 140 are completely enclosed by non-conductive and elastic material with the exception of their front and rear ends respectively.

The illustration in FIG. 28 shows schematic horizontal section through a part of a motor vehicle equipped with a switching strip profile 90 in accordance with the invention and as shown in FIGS. 15, 16 and 17. A vehicle body structure 142 of the vehicle is shown in the area of a rear opening that can be closed using a tailgate 144. A rear window 146 is arranged on the tailgate 144. The tailgate 144 can be opened and closed by an electric motor. To prevent the trapping of objects or limbs between the tailgate 144 and the vehicle body 142, the switching strip profile 90 is arranged on the tailgate 144 such that it protrudes furthest forward when seen from the tailgate 144 in the direction of the vehicle body 142. The switching strip profile 90 is connected by its carrier sheet 98 to a carrier 148, which in turn is fastened to the tailgate 144 by means of at least one expanding plug 150.

The illustration in FIG. 29 shows a schematic horizontal section through a part of a motor vehicle having a tailgate 144, said section being comparable to that in FIG. 28. Unlike the arrangement of the switching strip profile 90 in FIG. 28, the switching strip profile 90 in accordance with FIG. 29 is fastened by means of a carrier 152 to the body 142 of the motor vehicle. The carrier 152 is here connected by means of one or more expanding plugs 150 to the body 142. The switching strip profile 90 is arranged such that it protrudes furthest forward when seen from the body 142 in the direction of the tailgate 144.

The illustration in FIG. 30 shows a further schematic horizontal section through a part of a motor vehicle provided with a side sliding door 154 having the switching strip profile 90 in accordance with the invention. For this purpose, the switching strip profile 90 is fastened by means of a carrier 156 using one or more expanding plugs 150 to an end—at the front when seen in the travel direction—of the sliding door 154. The switching strip profile 90 therefore protrudes furthest forward when seen from the sliding door 154 in the direction of a driver's door 158. The driver's door 158 and the sliding door 154 pivot and slide respectively against a B-pillar 160 of the vehicle.

The illustration in FIG. 31 shows a further schematic horizontal section through a part of a motor vehicle provided with a switching strip profile 162 in accordance with the invention. The switching strip profile 162 has a form comparable to the switching strip profile 90, however a clamping section 164 is provided instead of a carrier sheet. The clamping section 164 is designed in the form of an open channel profile and has an approximately U-shaped clamping rail embedded in elastic rubber material. Elastic fingers 166 project into a cavity of the channel section and in the manner of barbs make it difficult to remove the switching strip profile 162 after sliding it onto a strip-like projection. The switching strip profile 162 is slid onto a strip-like projection 168 formed at the rear end of a side wall 170 of the vehicle. A front edge of the switching strip profile 162 projects furthest forward when seen from the side wall in the direction of a tailgate 172. Before an object or a human hand or arm is trapped between a front edge of the tailgate 172 or a front edge of the rear window 174, the approach of the object, hand or arm toward the switching strip profile 162 is detected before the latter is touched. A drive unit of the tailgate 172 can thus be stopped or reversed to prevent trapping.

1. A switching strip profile for a switching strip for the detection of obstructions having a profiled body (18) of electrically non-conductive material, a first conductor (12) arranged in a rear area of the profiled body (18) seen in the detection direction and a second conductor (14; 42) arranged in a front area of the profiled body (18) seen in the detection direction, characterized in that the first conductor (12) has, seen in a cross section of the profile, two side surfaces (26, 28) running substantially parallel and at a short distance from a respective outer wall (38) of the profiled body (18).

2. A switching strip profile according to claim 1, characterized in that the first conductor (12) has on its underside facing an attachment surface of the profile a U-shaped form opened towards the attachment surface.

3. A switching strip according to claim 1, characterized in that the first conductor (12) has on its upper side facing the second conductor (14; 42) a U-shaped form opened towards the second conductor (14; 42).

4. A switching strip according to claim 1, characterized in that a front surface (36) of the second conductor (14; 42), at the front when seen in the detection direction, is substantially parallel to an outer surface (38) of the profiled body (18).

5. A switching strip according to claim 4, characterized in that the front surface (36) of the second conductor (14; 42) is arranged at a distance from the outer surface (38) of the profiled body (18) which is greater than the distance of the side surfaces (26, 28) of the first conductor (12) from a respective side outer wall of the profiled body (18).

6. A switching strip according to claim 1, characterized in that a front surface (36) of the second conductor (14; 42) is designed arc-shaped when seen in the cross section of the profile.

7. A switching strip according to claim 1, characterized in that the profiled body (18) has a cavity (16; 46) abutted by an underside of the second conductor (14; 42) and an upper side of the first conductor (12).

8. A switching strip according to claim 7, characterized in that the second conductor (42) and/or the first conductor have a projection (44) protruding into the cavity (46) in the direction of the first conductor (12) or second conductor respectively.

9. An apparatus for the detection of obstructions having a switching strip with a switching strip profile in accordance with claim 1, characterized in that a control unit is provided, said control unit being coupled with low resistance to the first conductor and with high resistance to the second conductor, where an electrical field is generated in operation by means of the control unit and the first conductor, where an electrical field is formed between the second conductor and a reference potential due to the electrical field generated by the first conductor by capacitive coupling between the first conductor and the second conductor, and where a change in the capacitance between the second conductor and the reference potential caused by a obstruction is detected by the control unit.

10. An apparatus according to claim 9, characterized in that the first conductor and the second conductor are connected with high resistance by means of a terminating resistor.

11. An apparatus according to claim 10, characterized in that the control unit has means for detecting an interruption of the first and/or the second conductor.

12. An apparatus according to claim 9, characterized in that the control unit has means for detecting a mutual contact of the first and the second conductor.
